(19) United States
(12) Patent Application Publication
(10) Pub. No.: US 2005/0022744 A1
(43) Pub. Date: Feb. 3, 2005

(54) Susceptor for Semiconductor Manufacturing Equipment, and Semiconductor Manufacturing Equipment in Which the Susceptor Is Installed

(75) Inventors: Masuhiro Natsuhara, Itami-shi, Hyogo (JP); Hirohiko Nakata, Itami-shi, Hyogo (JP)

Correspondence Address: JUDGE PATENT FIRM;RIVIERE SHUKUGAWA 3RD FL., 3-1 WAKAMATSU-CHO, NISHINOMIYA-SHI, HYOGO, 662-0035, JP

(73) Assignee: SUMITOMO ELECTRIC INDUSTRIES, LTD., Osaka-shi (JP)

(21) Appl. No.: 10/710,727

(22) Filed: Jul. 30, 2004

(30) Foreign Application Priority Data
Aug. 1, 2003 (JP) JP-2003-205447

(51) Int. Cl. C23C 16/00

(52) U.S. Cl. 118/728

(57) ABSTRACT

Enhances the durability of electrodes for supplying electricity to electroconductive components formed in the interior and/or on the surface of a susceptor ceramic heater-block, affords for semi-conductor manufacturing equipment a susceptor in which incidents of inter-electrode shorting are prevented, and makes available semiconductor manufacturing equipment in which the susceptor is installed. Rendering as unitary articles the electrodes for supplying electricity to electroconductive components formed in the interior and/or on the surface of a ceramic heater-block contributes to improved electrode endurance. Further, setting up a tubular piece encompassing each electrode contributes to preventing incidents of shorting. Introducing inert gas into the interior of the tubular pieces further improves the reliability of the electrodes. Semiconductor manufacturing equipment of excellent productivity and throughput can be made available by installing a susceptor of this kind into the semiconductor manufacturing equipment.

### BACKGROUND OF INVENTION

1. Technical Field

The present invention relates to susceptors employed in semiconductor manufacturing equipment-such as devices for plasma CVD, low-pressure CVD, metal CVD, dielectric CVD, ion-implantation, etching, low-k deposition, and degassing—and furthermore to semiconductor manufacturing equipment in which such susceptors are installed.

2. Background Art

Conventionally, in semiconductor manufacturing procedures various processes, such as film deposition and etching, are carried out on semiconductor substrates that are the processed objects. Susceptors serving to retain semiconductor substrates are used in the processing devices in which such processes on semiconductor substrates are carried out.

As conventional susceptors of this sort, devices using a ceramic such as aluminum nitride have in recent years been proposed, and some of the proposed devices have been realized. Electroconductive components such as RF electrodes, electrodes for electrostatic chucks, and resistive heating elements are formed in the interior or on the surface of these ceramic susceptors. Various types of electrodes for supplying electricity to these electroconductive components have been proposed.

For example, a configuration in which rodlike terminals that are fatter than resistive heating elements and are attached to the ends of a resistive heating element, and in which electrode members are mechanically joined to the terminals in a plug fitting is proposed in Japanese Unexamined Pat. App. Pub. No. H04-87179. A problem with this structure, however, has been that the integrity of the joint in the mechanically joined portion of the structure has been compromised by the hot/cold (thermal) cycling of the susceptor and by the corrosive gases employed inside the processing chamber.

Another example of such electrode structures, proposed in Japanese Unexamined Pat. App. Pub. No. H05-175139, is furnished with a terminal electrically connected to each end of a resistive heating element embedded within ceramic, and a power-supplying member connected to the terminal. The structure includes a jacket around at least the space enveloping the terminal and the connection between the terminal and the power-supplying member, and is configured so that the inside of the jacket can be filled with a non-oxidative gas.

Nevertheless, although filling the jacket with non-oxidative gas serves to prevent corrosion, a problem in situations in which the terminals and the electrode members are of different substances has been that the integrity of the connection between the terminals and electrode members is compromised by thermal expansion and contraction due to hot/cold cycling.

What is more, if electrodes whose electric potentials differ are set up in the same space within the jacket, depending on the difference in electric potential across—and the separation between—the electrodes, as well as on the pressure of the atmosphere within the jacket, sparking between the electrodes will occur. When joint areas are present in the electrodes, another problem has been that shorting through the joints is especially liable to occur.

### SUMMARY OF INVENTION

The present invention has been brought about to resolve the foregoing problems. In particular, an object of the present invention is to enhance the durability of electrodes for supplying electricity to electroconductive components formed in the interior and/or on the surface of a susceptor ceramic heater-block, and to afford for semi-conductor manufacturing equipment a susceptor in which incidents of inter-electrode shorting are prevented and make available semiconductor manufacturing equipment in which such a susceptor is installed.

A susceptor of the present invention for semiconductor manufacturing equipment is characterized in that an electrode for supplying electricity to an electroconductive component formed in the interior and/or on the surface of a ceramic heater-block of the susceptor, set up within the processing chamber of semiconductor manufacturing equipment, is defined from where it connects with the electroconductive component to outside the chamber. In particular, whereas conventionally the electrodes and the power-supplying members were connected within the chamber, in the present invention the electrodes do not have such connections.

The susceptor can also be rendered so that a tubular piece is formed encompassing the electrode, and an inert gas is introduced into the interior of the tubular piece. Another option is to render the susceptor so that the space within the interior of the tubular piece is isolated from the atmosphere inside the chamber, with the inert gas being introduced into the tubular piece interior.

Furthermore, with semiconductor manufacturing equipment in which a susceptor such as described above is installed, because there are no connecting portions in the electrodes, their durability and integrity is enhanced, enabling semiconductors to be manufactured over longer maintenance-free periods than with conventional devices.

From the following detailed description in conjunction with the accompanying drawings, the foregoing and other objects, features, aspects and advantages of the present invention will become readily apparent to those skilled in the art.

### BRIEF DESCRIPTION OF DRAWINGS

FIGS. 1 through 6 each illustrate a respective single example of the sectional structure of a susceptor of the present invention;

FIGS. 7 and 8 each show a respective single example of the sectional structure of a conventional susceptor;

FIGS. 9 through 12 each illustrate a respective further example of the sectional structure of a susceptor of the present invention;

FIGS. 13 and 14 each show a respective further example of the sectional structure of a conventional susceptor; and

FIG. 15 illustrates another single example of the sectional structure of a susceptor of the present invention.

### DETAILED DESCRIPTION

The inventors discovered that rendering as unitary articles the electrodes for supplying electricity to the electroconductive component formed in the interior and/or on the surface of the susceptor ceramic heater-block can dramatically heighten the durability of the electrodes.

What the electrodes are composed of is not particularly limited as long as the thermal expansion coefficient of the substance is close to the thermal expansion coefficient of the ceramic heater-block. For example, if the ceramic is a substance whose thermal expansion coefficient is comparatively small—such as aluminum nitride, silicon nitride, or silicon carbide—then tungsten, molybdenum, or tantalum is preferably utilized for the electrodes.

Especially in cases in which aluminum nitride, whose utilization in susceptors for semiconductor manufacturing equipment has increased in recent years owing to its superlative anti-corrosiveness and other properties, is the ceramic, tungsten or tantalum are particularly preferable electrode substances.

As another option, an iron-nickel-cobalt alloy, whose thermal expansion coefficient can be matched to the thermal expansion coefficient of the ceramic, can also be utilized for the electrodes. A caveat, however, is that since the thermal expansion coefficient of iron-nickel-cobalt alloys will change abruptly depending on the temperature, whether the alloys are an available option necessarily depends on the application and the temperature at which the electrodes are used.

In addition, the electrodes can be superficially treated to form a protective film thereon as needed. More specifically, if the electrodes are to be protected from an oxidizing atmosphere, the surface of the electrodes preferably is plated with nickel, gold, or silver. The electrodes can also be multi-plated with these metals. For example, plating the electrodes initially with nickel, and then plating gold or silver onto the nickel plating will further improve the electrodes' resistance to corrosion. The kind and combination of platings can be appropriately selected in accordance with the application, that is, with the temperature and atmosphere in which the electrodes are used.

Optionally, a flame-spray coating can be formed on the surface of the electrodes. For example, flame-spraying alumina or mullite onto the electrodes' surface contributes to improving their corrosion resistance against operational gases such as oxygen. As a further example, an aluminum nitride coating can be formed on the surface of the electrodes by superficially flame-spraying them with aluminum within a nitrogen atmosphere. Inasmuch as the ability of aluminum nitride to withstand corrosion is particularly outstanding, the coating is especially effective in improving the electrodes' corrosion resistance.

Nevertheless, if a ceramic such as that just mentioned is to be flame-sprayed onto the electrodes, then it is necessary that the portion of the electrodes that is electrically connected with the electroconductive component formed in the interior and/or on the surface of the susceptor ceramic heater-block not be flame-sprayed with the ceramic. The reason for this is that inasmuch as the foregoing ceramic is an insulator, if even the portion of the electrodes for electrical connection were flame-sprayed, then an electrical connection could not be established. Apart from the foregoing ceramic, another material with which the electrodes can be flame-sprayed is a metal such as nickel, gold, or silver.

Likewise, apart from plating and flame-spraying, thin-film forming techniques of all kinds, such as ion plating, CVD, sputtering, and vacuum evaporation, can be adopted as ways of forming the foregoing protective coating. The type of protective film and the method of its formation can be chosen to suit, according to the various applications.

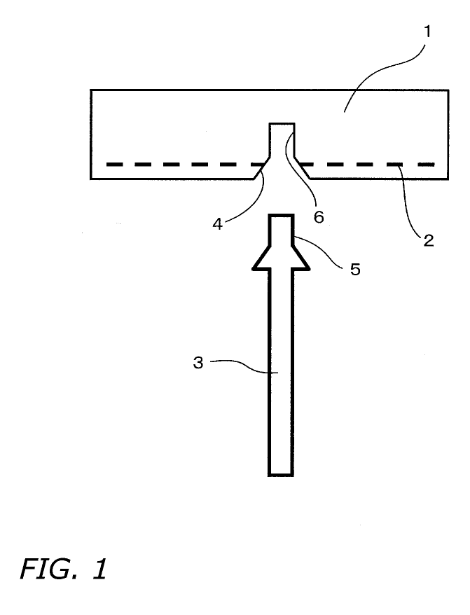

Next, methods according to the present invention of electrically connecting the foregoing electrodes with the electroconductive component formed in the interior and/or on the surface of the susceptor ceramic heater-block will be explained. Reference is made to FIG. 1, in which from within a ceramic heater-block 1, an electroconductive component 2 formed in the heater block is exposed. The fore end of an electrode 3 is male-screw 5 threaded, and the ceramic heater-block is female-screw 6 tapped; screwing the electrode 3 into the ceramic heater-block 1 to directly contact the electrode with the electroconductive component enables a stabilized electrical connection to be achieved.

Chamfering the exposed area of the heater block 1 into a countersink further stabilizes the electrical connection in this configuration. In addition, forming a metal film on the countersink 4 by a metallization process augments the contact surface area of the electrical connection, which improves the reliability of the electrical connection. As a separate method for doing so, inserting metal foil into the countersink 4 similarly enables the contact surface area to be increased. Although the metal foil that is inserted may be the same substance as that of the electrode, with the objective of both increasing the surface area and reducing the contact resistance, soft metals such as gold and silver as well as copper and aluminum are preferable.

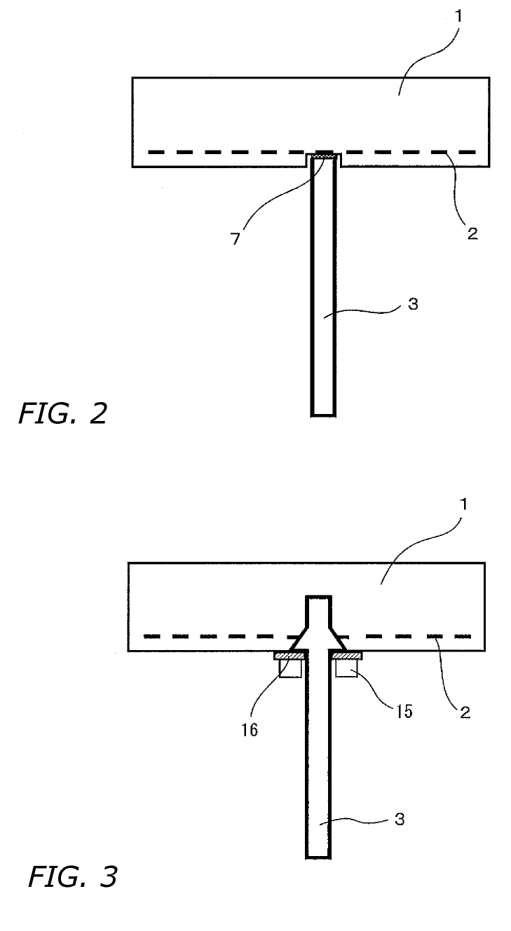

Another connection method that is possible is, as illustrated in FIG. 2, to braze the electrode 3 to the electroconductive component 2 employing a brazing fillet 7. A silver brazing material or an active metal brazing material can be employed as the brazing fillet. Although in this way the electrode and the electroconductive component are electrically connected, the corrosion resistance in the connecting region suffers, and thus it is preferable that, utilizing a ceramic member 15 as depicted in FIG. 3, the connection be sealed by means of glass 16. Sealing the connection in this way stops oxygen and reaction gases from invading the connection region and thus further improves the reliability of the connection. It should be noted that if the connection method is that of FIG. 2, then it is preferable that the connection be sealed with the glass 16 in a way, as depicted in FIG. 9, that does not leave the electroconductive component 2 exposed.

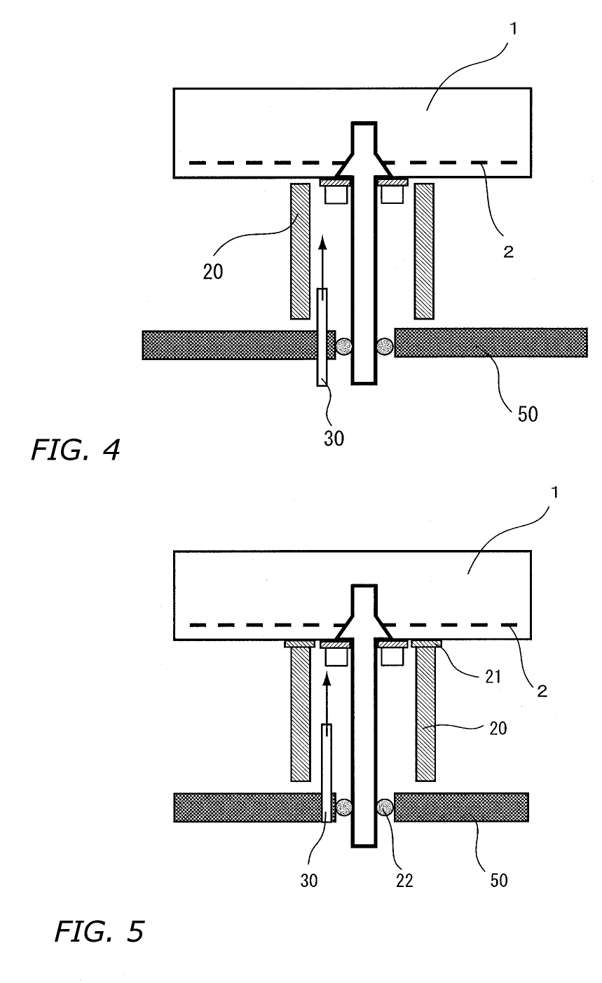

In a further aspect of the present invention, as illustrated in FIG. 4, a tubular piece 20 can be installed encompassing each electrode 3. The role of the tubular pieces 20 is to prevent shorting between the plural electrodes. It is especially advantageous to install tubular pieces in instances in which between electrodes the separation is short and the difference in electric potential is large. The tubular piece 20 is preferably of an insulative material that is heat-resistant. A further option in this aspect of the invention is to introduce inert gas into the interior of the tubular piece 20.

With electrodes of the present invention, the fact that joints, as with conventional electrodes, in the portion of the electrodes that is exposed do not exist means that inter-electrode shorting is not likely to occur. In other words, if joints or seams are present in the electrodes, with those areas as starting points shorting is especially prone to occur, yet inasmuch as such joints and seams do not exist in the electrodes of the present invention, shorting incidents are unlikely. Still, in order to improve the reliability of the electrodes further, a configuration in which tubular pieces as described above are installed is advantageous.

In a further aspect of the present invention, as depicted in FIG. 5, each tubular piece 20 can be joined to the ceramic heater-block 1 and inert gas introduced into the interior of the tubular piece 20. Introducing inert gas into the interior of the tubular piece 20 contributes to more reliably preventing exposure of the electrodes to corrosive gases, and thus improves the electrodes' endurance. The inert gas is introduced through a gas-introduction line 30. Gas that has been introduced into the tubular-piece interior is discharged through a clearance between the tubular pieces and the chamber 50. As long as the inert gas is one that does not react with the electrodes it should be fine, but from a cost aspect nitrogen and argon are preferable gases.

Another feasible configuration according to the present invention is to isolate the space inside the tubular pieces from the atmosphere inside the processing chamber of the semiconductor manufacturing equipment. Isolating the tubular-piece interior space makes the prevention of inter-electrode shorting the more reliable and completely eliminates exposure of the electrodes to corrosive gases, thus further enhancing the durability of the electrodes. One isolation method is for example a technique in which the tubular pieces are joined to the ceramic heater-block with glass or an active metal brazing material, and the interval in between the tubular pieces and the chamber is hermitically sealed with an O-ring. The substance of which the tubular pieces is made-inasmuch as they are joined to the ceramic heater-block-preferably is the same as the heater-block ceramic, or is a substance whose difference in thermal expansion coefficient with the heater-block ceramic is 5×10⁻⁶ or less.

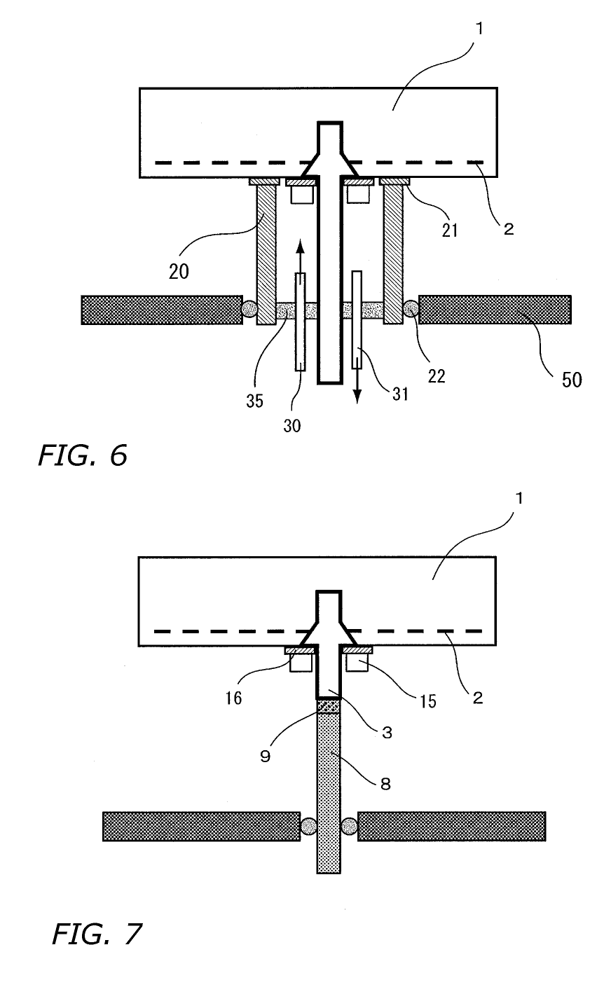

In this case as well, flowing inert gas into the interior of the tubular pieces contributes to improving the durability of the electrodes. An example is as illustrated in FIG. 6, in which: each tubular piece 20 is joined to the ceramic heater-block 1 by means of a joining material 21; the interval in between the tubular piece 20 and the chamber 50 is hermetically sealed via an O-ring 22; the interval in between the tubular piece 20 and the electrode is sealed off with a synthetic polymer or like sealing material 35; and through the gas-introduction line 30 gas is introduced, and through a gas-discharge pipe 31 gas is discharged. Likewise as noted earlier, while an inert gas that does not react with the electrodes should be fine, from a cost aspect nitrogen and argon are preferable gases.

Making electrodes as in the foregoing unitary articles in which there are no seams enables preventing corrosion of the electrodes due to the corrosive gases employed in semiconductor manufacturing equipment and to oxygen in the atmosphere, wherein electrodes of enhanced integrity against thermal cycling due to the raising and lowering of the susceptor temperature can be rendered.

Although the substantive material of a ceramic heater-block in the present invention is not particularly limited as long as the material is an insulative ceramic, aluminum nitride (AIN), being highly thermoconductive and superlative in corrosion resistance, is preferable. In the following, a method according to the present invention of manufacturing a ceramic heater-block in the case of AIN will be detailed.

AIN raw material powder whose specific surface area is 2.0 to 5.0 m²/g is preferable. The sinterability of the aluminum nitride declines if the specific surface area is less than 2.0 m²/g. Handling proves to be a problem if on the other hand the specific surface area is over 5.0 m²/g, because the powder coherence becomes extremely strong. Furthermore, the quantity of oxygen contained in the raw-material powder is preferably 2 wt. % or less. In sintered form, the thermal conductivity of the material deteriorates if the oxygen quantity is in excess of 2 wt. %. It is also preferable that the amount of metal impurities other than aluminum contained in the raw-material powder be 2000 ppm or less. The thermal conductivity of a sintered compact of the powder deteriorates if the amount of metal impurities exceeds this range. In particular, the content respectively of Group IV elements such as Si, and elements of the iron family, such as Fe, which as metal impurities have a serious worsening effect on the thermal conductivity of a sintered compact, is advisably 500 ppm or less.

Because AIN is not a readily sinterable material, adding a sintering promoter to the AIN raw-material powder is advisable. The sintering promoter added preferably is a rare-earth element compound. Since rare-earth element compounds during sintering react with aluminum oxides or aluminum oxynitrides present on the surface of the particles of the aluminum nitride powder, acting to promote densification of the aluminum nitride and to eliminate oxygen being a causative factor that worsens the thermal conductivity of the aluminum nitride sintered part, they enable the thermal conductivity of the aluminum nitride sintered part to be improved.

Yttrium compounds, whose oxygen-eliminating action is particularly pronounced, are preferable rare-earth element compounds. The amount added is preferably 0.01 to 5 wt. %. If less than 0.01 wt. %, producing ultrafine sintered materials is problematic, along with which the thermal conductivity of the sintered parts deteriorates. Added amounts in excess of 5 wt. % on the other hand lead to sintering promoter being present at the grain boundaries in the aluminum nitride sintered part, and consequently, if the compact is employed under a corrosive atmosphere, the sintering promoter present along the grain boundaries gets etched, becoming a source of loosened grains and particles. More preferably the amount of sintering promoter added is 1 wt. % or less. Being less than 1 wt. %, the sintering promoter will no longer be present even at the grain boundary triple points, which improves the corrosion resistance.

To characterize the rare-earth compounds further: oxides, nitrides, fluorides, and stearic oxide compounds may be employed. Among these, oxides, being inexpensive and readily obtainable, are preferable. By the same token, stearic oxide compounds are especially suitable since they have a high affinity for organic solvents, and if the aluminum nitride raw-material powder, sintering promoter, etc. are to be mixed together in an organic solvent, the fact that the sintering promoter is a stearic oxide compound will heighten the miscibility.

Next, a predetermined volume of solvent, a binder, and further, a dispersing agent or a coalescing agent as needed, are added to the aluminum nitride raw-material powder and powdered sintering promoter, and the mixture is blended together. Possible mixing techniques include ball-mill mixing and mixing by ultrasound. Mixing techniques of this sort allow a raw-material slurry to be produced.

The obtained slurry is molded, and the molded product is sintered to yield a sintered aluminum-nitride part. Cofiring and metallization are two possible methods as a way of doing this.

Metallization will be described first. Granules are prepared from the slurry by spray-drying it, or by means of a similar technique. The granules are inserted into a predetermined mold and subject to press-molding. The pressing pressure therein desirably is 10 MPa (0.1 t/cm²) or more. With pressure less than 10 MPa (0.1 t/cm²), sufficient strength in the molded part cannot be produced in most cases, making the piece liable to break in handling.

Although the density of the molded part will differ depending on the amount of binder contained and on the amount of sintering promoter added, the density is preferably 1.5 g/cm³ or more. A density of less than 1.5 g/cm³ would mean a relatively large distance between particles in the raw-material powder, which would hinder the progress of the sintering. At the same time, the molded product density preferably is 2.5 g/cm³ or less. Densities of more than 2.5 g/cm³ would rule out sufficiently eliminating the binder from within the molded product in the degreasing process of the ensuing manufacturing procedure. It would consequently prove difficult to produce an ultrafine sintered part as described earlier.

Next, the molded product is heated within a non-oxidizing atmosphere to put it through a degreasing process. Carrying out the degreasing process under an oxidizing atmosphere such as air would degrade the thermal conductivity of the sinter, because the AIN powder would become superficially oxidized. For the non-oxidizing ambient gases, nitrogen and argon are preferable. The heating temperature in the degreasing process is preferably 500° C. or more and 1000° C. or less. With temperatures of less than 500° C., carbon is left remaining in excess within the molded part following the degreasing process because the binder cannot sufficiently be eliminated, which interferes with sintering in the subsequent sintering procedure. On the other hand, at temperatures of more than 1000° C., the amount of carbon left remaining turns out to be too little, such that the ability to eliminate oxygen from the oxidized coating superficially present on the surface of the AIN powder is compromised, degrading the thermal conductivity of the sintered part.

Another condition is that the amount of carbon left remaining within the molded product after the degreasing process is preferably 1.0 wt. % or less. Since carbon remaining in excess of 1.0 wt. % interferes with sintering, an ultrafine sintered part cannot be produced.

Next, sintering is carried out. The sintering is carried out within a non-oxidizing nitrogen, argon, or like atmosphere, at a temperature of 1700 to 2000° C. Therein the moisture contained in the ambient gas, such as nitrogen, that is employed is preferably −30° C. or less given in dew point. If the atmosphere were to contain more moisture than this, the thermal conductivity of the sintered part would likely be compromised, because the AIN would react with the moisture within the ambient gas during sintering and form nitrides. Another preferable condition is that the volume of oxygen within the ambient gas be 0.001 vol. % or less. A larger volume of oxygen would lead to a likelihood of the AIN becoming superficially oxidized, impairing the thermal conductivity of the sintered part.

As another condition during sintering, the jig employed is suitably a boron-nitride (BN) molded article. Inasmuch as the jig as a BN molded article will be sufficiently heat resistant against the sintering temperatures, and superficially will have solid lubricity, friction between the jig and the molded part when the block contracts during sintering will be lessened, which will enable sinter products with little distortion to be produced.

The obtained sintered part is subjected to processing according to requirements. In cases where a conductive paste is to be screen-printed onto the sintered part in the ensuing manufacturing steps, the surface roughness is preferably 5 □m or less in Ra. If over 5 □m, in screen printing to form a circuit on the compact, defects such as blotting or pinholes in the pattern are liable to arise. More suitable is a surface roughness of 1 □m or less in Ra.

In polishing to the abovementioned surface roughness, although cases in which screen printing is done on both sides of the sintered part are a matter of course, even in cases where screen printing is effected on one side only, the polishing process should also be carried out on the surface on the side opposite the screen-printing face. This is because polishing only the screen-printing face would mean that during screen printing, the sintered part would be supported on the unpolished face, and in that situation burrs and debris would be present on the unpolished face, destabilizing the fixedness of the sintered part such that the circuit pattern might not be drawn well by the screen printing.

Furthermore, at this point the thickness uniformity (parallelism) between the processed faces is preferably 0.5 mm or less. Thickness uniformity exceeding 0.5 mm can lead to large fluctuations in the thickness of the conductive paste during screen printing. Particularly suitable is a thickness uniformity of 0.1 mm or less. Another preferable condition is that the planarity of the screen-printing face be 0.5 mm or less. If the planarity exceeds 0.5 mm, in that case too there can be large fluctuations in the thickness of the conductive paste during screen printing. Particularly suitable is a planarity of 0.1 mm or less.

Screen printing is used to spread a conductive paste and form the electroconductive component (electrical circuitry) onto the sintered part having undergone the polishing process. The conductive paste can be obtained by mixing together with a metal powder an oxide powder, a binder, and a solvent according to requirements. The metal powder is preferably tungsten, molybdenum or tantalum, since their thermal expansion coefficients match those of ceramics.

Adding the oxide powder to the conductive paste is also to enhance the strength with which it bonds to AIN. The oxide powder preferably is an oxide of Group ha or Group IIIa elements, or is Al₂O₃, SiO₂, or a like oxide. Yttrium oxide is especially preferable because it has very good wettability with AIN. The amount of such oxides added is preferably 0.1 to 30 wt. %. If the amount is less than 0.1 wt. %, the bonding strength between AIN and the metal layer being the circuit that has been formed is compromised. On the other hand, amounts in excess of 30 wt. % elevate the electrical resistance of the metal layer that is the electrical circuit.

The thickness of the conductive paste is preferably 5 □m or more and 100 □m or less in terms of its post-drying thickness. If the thickness is less than 5 □m the electrical resistance would be too high and the bonding strength would decline. Likewise, if in excess of 100 □m the bonding strength would be compromised in that case as well.

Also preferable is that in the patterns for the circuits that are formed, in the case of the heater circuit (resistive heating element circuit), the pattern spacing be 0.1 mm or more. With a spacing of less than 0.1 mm, shorting will occur when current flows in the resistive heating element and, depending on the applied voltage and the temperature, leakage current is generated. Particularly in cases where the circuit is employed at temperatures of 500° C. or more, the pattern spacing preferably should be 1 mm or more; more preferable still is that it be 3 mm or more.

After the conductive paste is degreased, baking follows. Degreasing is carried out within a non-oxidizing nitrogen, argon, or like atmosphere. The degreasing temperature is preferably 500° C. or more. At less than 500° C., elimination of the binder from the conductive paste is inadequate, leaving behind in the circuit metal layer carbon that when the circuit is baked on will form metal carbides and consequently raise the electrical resistance of the metal layer.

The baking is suitably done within a non-oxidizing nitrogen, argon, or like atmosphere at a temperature of 1500° C. or more. At temperatures of less than 1500° C., the post-baking electrical resistance of the metal layer turns out too high because the baking of the metal powder within the paste does not proceed to the grain growth stage. A further baking parameter is that the baking temperature should not surpass the sintering temperature of the ceramic produced. If the conductive paste is baked at a temperature beyond the sintering temperature of the ceramic, dispersive volatilization of the sintering promoter incorporated within the ceramic sets in, and moreover, grain growth in the metal powder within the conductive paste is accelerated, impairing the bonding strength between the ceramic and the metal layer.

Next, in order to ensure that the formed metal layer is electrically isolated, an insulative coating can be formed on the metal layer. Preferably the insulative coating substance is the same substance as the ceramic on which the metal layer is formed. Problems such as post-sintering warpage arising from the difference in thermal expansion coefficients will occur if the ceramic and insulative coating substances differ significantly. For example, in a case where the ceramic is AIN, a predetermined amount of, as a sintering promoter, an oxide/carbide of a Group ha element or a Group IIIa element can be added to and mixed together with AIN powder, a binder and a solvent added and the mixture rendered into a paste, and the paste can be screen-printed to spread it onto the metal layer.

In that case, the amount of sintering promoter added preferably is 0.01 wt. % or more. With an amount less than 0.01 wt. % the insulative coating does not densify, which is prohibitive of ensuring electrical isolation of the metal layer. It is further preferable that the amount of sintering promoter not exceed 20 wt. %. Surpassing 20 wt. % leads to excess sintering promoter invading the metal layer, which can end up altering the metal-layer electrical resistance. Although not particularly limited, the spreading thickness preferably is 5 □m or more. This is because securing electrical isolation proves to be problematic at less than 5 □m.

Next, in the present method, the ceramic as substrates furthermore can be laminated according to requirements. Lamination may be done via an adhesive. The adhesive—being a compound of Group IIa or Group IIIa elements, and a binder and solvent, added to an aluminum oxide powder or aluminum nitride powder and made into a paste—is spread onto the joining surface by a technique such as screen printing. The thickness of the applied adhesive is not particularly restricted, but preferably is 5 □m or more. Joining defects such as pinholes and adhesive irregularities are liable to arise in the adhesive layer at thicknesses of less than 5 □m.

The ceramic substrates onto which the adhesive has been spread are degreased within a non-oxidizing atmosphere at a temperature of 500° C. or more. The ceramic substrates are thereafter joined to one another by stacking together ceramic substrates to be laminated, applying a predetermined load to the stack, and heating it within a non-oxidizing atmosphere. The load preferably is 5 kPa (0.05 kg/cm²) or more. With loads of less than 5 kPa (0.05 kg/cm²) sufficient joining strength will not be obtained, and otherwise the joining defects just noted will be prone to occur.

Although the heating temperature for joining is not particularly restricted as long as it is a temperature at which the ceramic substrates adequately bond to one another via the joining layers, preferably it is 1500° C. or more. With adequate joining strength proving difficult to gain at less than 1500° C., defects in joining are liable to arise. Nitrogen or argon is preferably employed for the non-oxidizing atmosphere during the degreasing and joining just discussed.

A ceramic sinter laminate that serves as a ceramic heater-block can be produced as in the foregoing. As far as the electrical circuitry is concerned, it should be understood that if it is a heater circuit for example, then a molybdenum coil can be utilized, and in cases such as with electrostatic-chuck electrodes or RF electrodes, molybdenum or tungsten mesh can be, without employing conductive paste.

In such cases, the molybdenum coil or the mesh can be built into the AIN raw-material powder, and the ceramic heater-block can be fabricated by hot pressing. While the temperature and atmosphere in the hot press may be on par with the AIN sintering temperature and atmosphere, the hot press desirably applies a pressure of 1 MPa (10 kg/cm²) or more. With pressure of less than 1 MPa (10 kg/cm²), the ceramic heater-block might not demonstrate its performance capabilities, because interstices arise between the AIN and the molybdenum coil or the mesh.

Co-firing will now be explained. The earlier-described raw-material slurry is molded into sheets by doctor blading. The sheet-molding parameters are not particularly limited, but the post-drying thickness of the sheets advisably is 3 mm or less. The sheet thickness surpassing 3 mm leads to large shrinkage in the drying slurry, raising the probability that fissures will be generated in the sheet.

A metal layer of predetermined form that serves as an electrical circuit is formed onto an abovementioned sheet using a technique such as screen printing to spread onto it a conductive paste. The conductive paste utilized can be the same as that which was descried under the metallization method. Nevertheless, not adding an oxide powder to the conductive paste does not hinder the co-firing method.

Subsequently, the sheet that has undergone circuit form ation is laminated with sheets that have not. Lamination is by setting the sheets each into predetermined position to stack them together. Therein, according to requirements, a solvent is spread on between sheets. In the stacked state, the sheets are heated as may be necessary. In cases where the stack is heated, the heating temperature is preferably 150° C. or less. Heating to temperatures in excess of this greatly deforms the laminated sheets. Pressure is then applied to the stacked-together sheets to unitize them. The applied pressure is preferably within a range of from 1 to 100 MPa. At pressures less than 1 MPa, the sheets are not adequately unitized and can peel apart during subsequent manufacturing steps. Likewise, if pressure in excess of 100 MPa is applied, the extent to which the sheets deform becomes too great.

This laminate undergoes a degreasing process as well as sintering, in the same way as with the metallization method described earlier. Parameters such as the temperature in degreasing and sintering, and the amount of carbon are the same as with metallization. A ceramic heater-block having plural electrical circuitry can be readily fabricated by printing, in the previously described screen printing of a conductive paste onto sheets, heater circuits, electrostatic-chuck electrodes, etc. respectively onto a plurality of sheets and laminating them. In this way a ceramic sinter laminate that serves as a wafer holder can be produced.

The obtained ceramic sinter laminate is subject to processing according to requirements. As a rule, in the sintered state the ceramic sinter laminate usually is not within the precision demanded in semiconductor manufacturing equipment. The planarity of the wafer-carrying side as an example of processing precision is preferably 0.5 mm or less; moreover 0.1 mm or less is particularly preferable. The planarity surpassing 0.5 mm is apt to give rise to interstices between the ceramic heater-block and a wafer the ceramic heater-block carries, keeping the heat of the ceramic heater-block from being uniformly transmitted to the wafer and making the generation of temperature irregularities in the wafer likely.

A further preferable condition is that the surface roughness of the wafer-carrying side be 5 □m in Ra. If the roughness is over 5 □m in Ra, grains loosened from the AIN due to friction between the ceramic heater-block and the wafer can grow numerous. Grain-loosened particles in that case become contaminants that have a negative effect on processes, such as film deposition and etching, on the wafer. Furthermore, then, a surface roughness of 1 □m or less in Ra is ideal.

A base part for a ceramic heater-block can thus be fabricated as in the foregoing. The ceramic heater-block can be rendered into a susceptor for semiconductor manufacturing equipment by attaching electrodes to the ceramic heater-block as described earlier and setting it up in semiconductor manufacturing equipment. The fact that the electrodes in this semiconductor-manufacturing-equipment susceptor are seamless dramatically improves the electrodes' durability and contributes to rendering semiconductor manufacturing equipment of high reliability.

While embodiments are set forth in the following, they are ultimately only single examples; the present invention is not limited to these embodiments.

Embodiments

Embodiment 1—99 parts by weight aluminum nitride powder and 1 part by weight Y₂O₃ powder were mixed and blended with 10 parts by weight polyvinyl butyral as a binder and 5 parts by weight dibutyl phthalate as a solvent. The mixing was carried out in a ball mill for 24 hours to prepare a slurry. The slurry was granulated by spray-drying. The granules were charged into a mold of predetermined form and pressure-molded to produce a molded part. After being degreased within a nitrogen atmosphere at 800° C., the molded part was sintered 6 hours at 1850° C. in a nitrogen atmosphere to yield a sintered AIN part. Here, an aluminum nitride powder of 0.6 □m mean particle diameter and 3.4 m²/g specific surface area was utilized.

Furthermore, a tungsten paste was prepared with a tungsten powder of 2.0 □m mean particle diameter being 100 parts by weight, by mixing it with Y₂O₃ at 1 part by weight, 5 parts by weight ethyl cellulose, being a binder, and as a solvent, butyl Carbitol™. A pot mill and a triple-roller mill were used for mixing. This tungsten paste was formed into a heater circuit pattern on the foregoing sintered AIN part by screen-printing. By degreasing this within an 800° C. nitrogen atmosphere and subsequently baking it 6 hours in a nitrogen atmosphere at 1800° C., a tungsten electroconductive-component circuit atop a sintered AIN part was created.

In addition, a ceramic paste was prepared by adding a binder and an organic solvent to a powder composed of 20 parts by weight AIN, 30 parts by weight Y₂O₃, with the remainder being Al₂O₃. This ceramic paste was by screen-printing spread onto the sintered AIN part over the entire surface where the tungsten electroconductive-component circuit was formed, and after being dried the sintered AIN part thus coated was degreased within a nitrogen atmosphere at 800° C.

After degreasing the thus-finished sintered AIN part, onto the face on which the ceramic had been coated a separately prepared sintered AIN part was stacked and the stack was hot-pressed 2 hours under a pressure of 2 MPa (20 kg/cm²) within a 1800° C. nitrogen atmosphere, whereby a ceramic heater-block was produced. This will be called “ceramic heater-block A.”

This ceramic heater-block A was countersunk as indicated in FIG. 1 so as to expose the electroconductive component, and was tapped with M3 threads 6. After the tapping process, tungsten electrodes 3 of the form depicted in FIG. 1, plated with 2 □m nickel, were screwed into the countersinks. Following that the joint between each tungsten electrode and the electroconductive component in the ceramic heater-block was sealed off by joining a ring 15 as shown in FIG. 3, made of AIN, to the ceramic heater-block with glass 16. The glass utilized was a ZnO₂—SiO₂—B₂O₃ glass-ceramic, and the sealing temperature was 750° C.

This susceptor was set up in semiconductor manufacturing equipment, where it underwent 10 test cycles of heating up and cooling down between room temperature and 600° C. within air. In addition, the susceptor underwent 10 cycles of a heat-up/cool-down test between room temperature and 600° C. with the atmosphere made CF₄, which is a corrosive gas. The result was that in the tungsten electrodes after either test, although somewhat of a color change was observed, there was nothing unusual in their electrical continuity to the electroconductive component.

Embodiment 2—A tubular piece 20 made of AIN, 50 mm outer diameter, 40 mm inner diameter and 200 mm length, around each tungsten electrode was set in place on an AIN susceptor of the same form as that of Embodiment 1; and while nitrogen gas was introduced through the gas-introduction lines 30, the same heat-up/cool-down tests as in Embodiment 1 were performed. The result was that there were no problems with electrical continuity at all, while the color-change in the tungsten electrodes was slighter than was the case in Embodiment 1.

Embodiment 3—AIN tubular pieces were joined onto the susceptor utilized in Embodiment 1. With the ceramic paste utilized in Embodiment 1 as the joining material 21 after being degreased at 800° C., the tubular pieces were joined on by hot-pressing within a nitrogen atmosphere 1 hour at 1780° C.

Similarly with Embodiment 2, the result of performing the same heat-up/cool-down tests as in Embodiment 1 while nitrogen gas was introduced through the gas-introduction lines 30 was that there were no problems with electrical continuity, and no color-change in the tungsten electrodes.

Embodiment 4—The susceptor and tubular pieces utilized in Embodiment 3 were utilized, and the end portion of the tubular pieces was sealed off, as represented in FIG. 6, with a plastic resin 35. After making the interior of the tubular pieces 20 into a nitrogen atmosphere by introducing nitrogen gas through the gas-introduction lines 30 and discharging it through the gas-discharge pipes 31, the same heat-up/cool-down tests as in Embodiment 1 were conducted. The result was that there were no problems at all with electrical continuity, and no color-change at all in the tungsten electrodes.

### COMPARATIVE EXAMPLE 1

Electrodes as depicted in FIG. 7 were attached to the countersunk and thread-tapped ceramic heater-block A utilized in Embodiment 1. In particular, the electrodes were not unitary articles; they were each rendered a compound electrode in which the length of the tungsten electrode 3 was made shorter than in Embodiment 1, and a nickel electrode 8 was brazed to the tungsten electrode 3 with silver brazing solder 9. The brazing was carried out in hydrogen at 840° C. In the same way as in Embodiment 1, the AIN rings 15 were joined on with glass 16 to seal the joints between the tungsten electrodes and the electroconductive component.

This susceptor was used to conduct the same heat-up/cool-down tests as in Embodiment 1, wherein the brazing joint in an electrode ruptured in the third cycle of the heat-up/cool-down test in air. In turn, while there was no rupturing in the test in the CF₄ atmosphere, the silver brazing solder portions of the electrodes were seriously etched.

### COMPARATIVE EXAMPLE 2

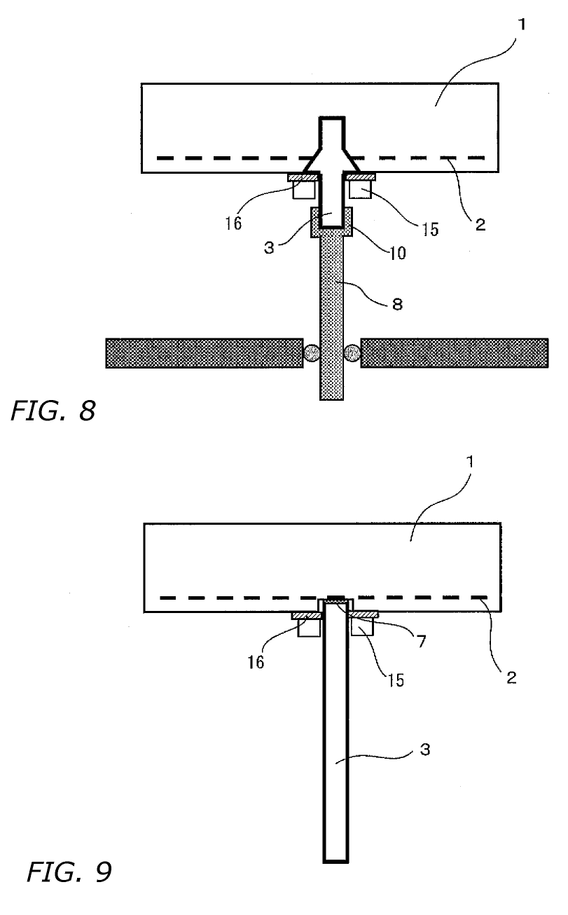

Electrodes as shown in FIG. 8 were attached to the countersunk and thread-tapped ceramic heater-block A utilized in Embodiment 1. In particular, the electrodes were not unitary articles; they were each rendered a compound electrode in which the length of the tungsten electrode 3 was made shorter than in Embodiment 1, and a nickel electrode 8 was attached, by a screw portion 10 thereof, to the tungsten electrode 3. In the same way as in Embodiment 1, the AIN rings 15 were joined on with glass 16 to seal the joints between the tungsten electrodes and the electroconductive component.

This susceptor was used to conduct the same heat-up/cool-down tests as in Embodiment 1, wherein spark marks were present following both the in-air and CF atmosphere tests, with a portion of the threads being fused. Furthermore, somewhat of a color-change was visible in the tungsten electrodes.

Embodiment 5—The foregoing ceramic heater-block A was countersunk into the FIG. 2 form so as to expose the electroconductive component 2. Molybdenum electrodes 3 that, apart from their two ends, were flame-sprayed with alumina were brazed as indicated in FIG. 2 to the exposed electroconductive component in a vacuum at 850° C. using an active brazing solder 5. An AIN ring was utilized likewise as with Embodiment 1 to glass-seal, as illustrated in FIG. 9, the brazing joint between the electroconductive component 2 and each molybdenum electrode 3. The heat-up/cool-down tests between room temperature and 600° C. were performed in the same manner as in Embodiment 1. The result was that in air and in CF₄, although the alumina on the molybdenum electrodes discolored somewhat, as far as the electrical continuity was concerned there were no problems whatsoever.

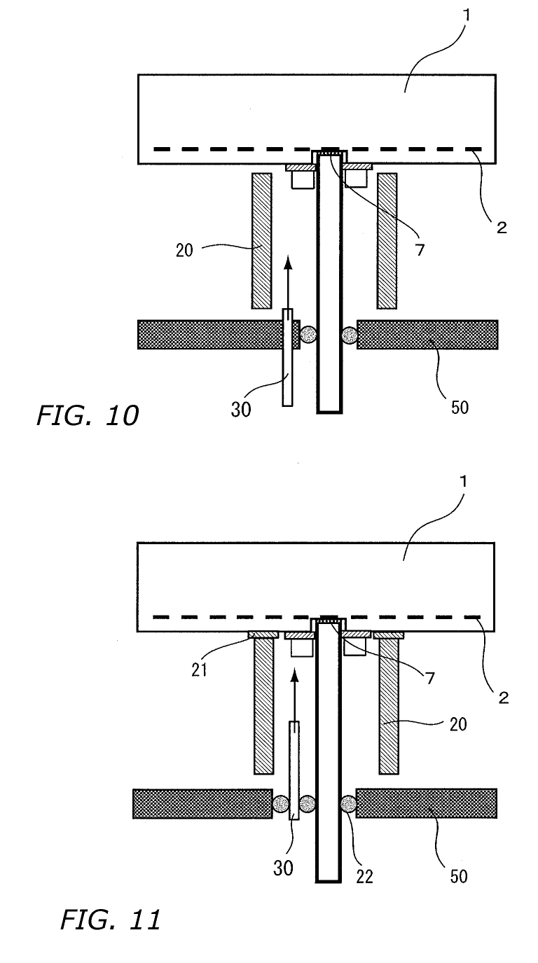

Embodiment 6—Apart from utilizing, likewise as in Embodiment 5, a ceramic heater-block onto which alumina-flame-sprayed molybdenum electrodes were brazed, a ceramic susceptor as in Embodiment 2 was fitted as illustrated in FIG. 10 with the same AIN tubular pieces and underwent the same heat-up/cool-down tests. The result was that as far as the electrical continuity was concerned there were no problems whatsoever, while the color-change was slighter than in Embodiment 5.

Embodiment 7—Apart from utilizing, as was the case in Embodiment 5, a ceramic heater-block onto which alumina-flame-sprayed molybdenum electrodes were brazed, a ceramic susceptor was lent the FIG. 11 configuration likewise as with Embodiment 3 and underwent the heat-up/cool-down tests. The result was that there were no problems at all with regard to electrical continuity, and there was no discoloration.

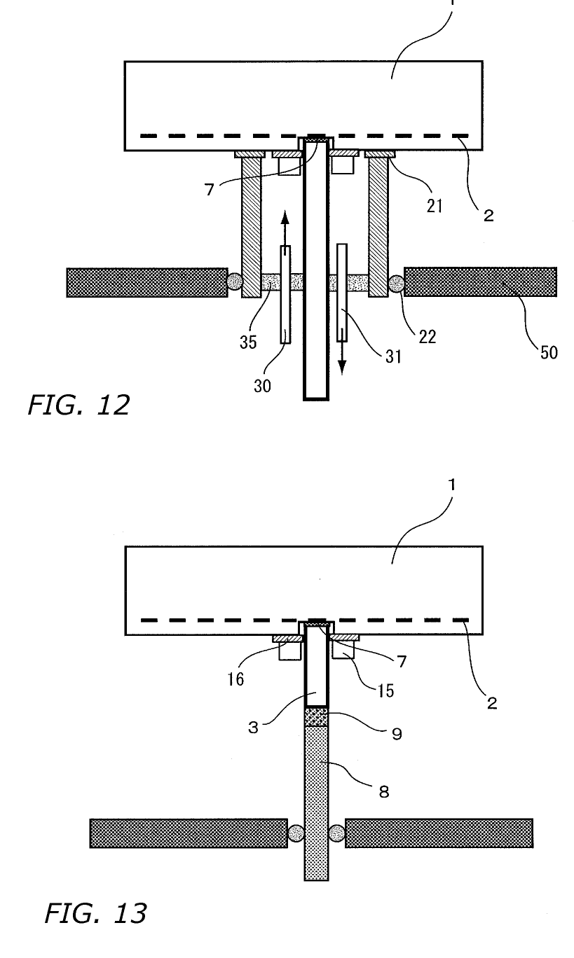

Embodiment 8—Apart from utilizing, as was the case in Embodiment 5, a ceramic heater-block onto which alumina-flame-sprayed molybdenum electrodes were brazed, a ceramic susceptor was lent the FIG. 12 configuration likewise as with Embodiment 4 and underwent the heat-up/cool-down tests. The result was that there were no problems at all with regard to electrical continuity, and there was no discoloration.

### COMPARATIVE EXAMPLE 3

A susceptor that, apart from its ceramic heater-block A being countersunk in the same way as in Embodiment 5 and its utilizing similar alumina-flame-sprayed molybdenum electrodes, had nickel electrodes 8 brazed on as shown in FIG. 13, likewise as with Comparative Example 1, underwent the heat-up/cool-down tests. The result was that the brazing joint in an electrode ruptured in the fourth cycle of the heat-up/cool-down test in air. In turn, while there was no rupturing in the test in the CF₄ atmosphere, the brazing joints were etched considerably.

### COMPARATIVE EXAMPLE 4

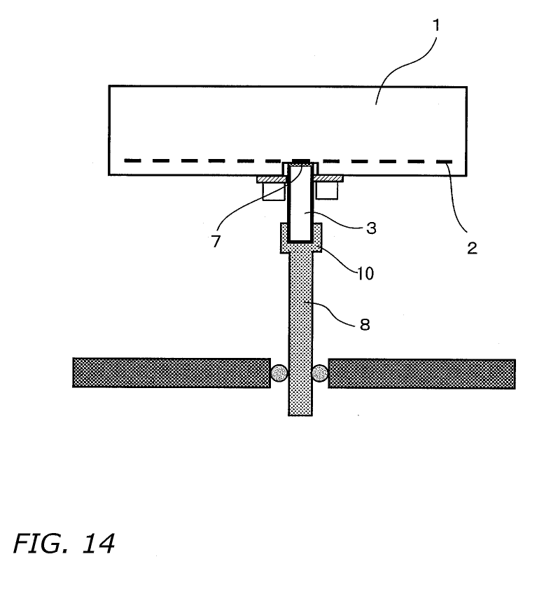

A susceptor that, apart from its ceramic heater-block A being countersunk in the same way as in Embodiment 5 and its utilizing similar alumina-flame-sprayed molybdenum electrodes, had nickel electrodes 8 screwed on as shown in FIG. 14, likewise as with Comparative Example 2, underwent the heat-up/cool-down tests. The result was that both within air and within the CF₄ atmosphere spark marks were present, and a portion of the threads fused. Furthermore, discoloration of the molybdenum electrodes occurred.

Embodiment 9—A tungsten electroconductive-component circuit (resistive-heating-element circuit) was formed onto a sintered AIN part in the same manner as in Embodiment 1, and a tungsten electroconductive-component circuit for generating high RF power was formed on the surface on the opposite side of the AIN part. Two separate sintered AIN parts were coated with ceramic paste likewise as with Embodiment 1 and were degreased; thereafter the sintered AIN part on which the electroconductive-component circuits were formed was sandwiched in between the other two AIN parts and the sandwich was joined together by hot-pressing. In addition, tungsten electrodes were attached, in the same manner as in Embodiment 1, to the tungsten electroconductive-component circuit being a resistive-heating-element circuit, and to the tungsten electroconductive-component circuit for generating high RF power, and the joints were sealed with AIN rings and glass. The separation between these tungsten electrodes was 5 mm.

This susceptor was set up in semiconductor manufacturing equipment, where it was pumped down to a 10 Pa vacuum. A voltage of 150 V was then applied to the resistive-heating-element circuit to heat the susceptor to 500° C. Subsequently voltage at a frequency of 13.56 MHz was gradually applied to the tungsten electroconductive-component circuit for generating high RF power, and the short-circuiting voltage was measured. The result was that shorting occurred at 3500 V.

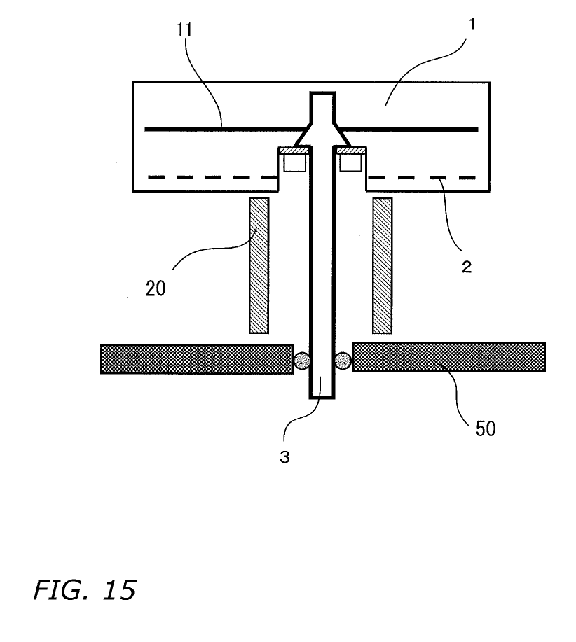

Next, as represented in FIG. 15 tubular pieces of a mullite-alumina composite were set in place so as to encompass the tungsten electrodes 3 connected to the high-RF-generating electroconductive component 11. It will be appreciated that only one tungsten electrode is illustrated in FIG. 15, with the other tungsten electrodes being omitted. Utilizing this susceptor the short-circuiting voltage was measured as noted above; up until 5000 V there was no shorting.

### COMPARATIVE EXAMPLE 5

The same susceptor as that of Embodiment 9, formed with the resistive-heating-element circuit and the high-RF-generating circuit was utilized; onto the susceptor were attached not the one-piece tungsten electrodes as in Embodiment 9, but as shown in FIG. 7 compound electrodes in which a nickel electrode was brazed onto a tungsten electrode. No tubular pieces were fitted on, and the short-circuiting voltage was measured in the same way as in Embodiment 9, wherein shorting occurred at 1700 V. The electrodes were inspected after the shorting, which indicated that the shorting had occurred in the brazing joints 9.

Embodiment 10—Susceptors of the configurations of Embodiments 1 through 8 were set up in semiconductor manufacturing equipment, wherein a tungsten film was formed onto a silicon wafer. Thereafter the inside of the semiconductor manufacturing equipment was cleaned using CF₄ gas, and the condition of the electrodes on each susceptor was inspected. The results were the same as the results in each of the embodiments themselves.

According to the present invention as in the foregoing, within the chamber making the electrodes unitary articles in which there are no seams or joints enables electrodes of enhanced integrity to be achieved against corrosive gases, oxygen, etc., and against thermal cycling due to the raising and lowering of the ceramic heater-block temperature. Susceptors having electrodes of this kind, and semiconductor manufacturing equipment in which the susceptors are installed can be lent heightened reliability and a long lifespan.

Only selected embodiments have been chosen to illustrate the present invention. To those skilled in the art, however, it will be apparent from the foregoing disclosure that various changes and modifications can be made herein without departing from the scope of the invention as defined in the appended claims. Furthermore, the foregoing description of the embodiments according to the present invention is provided for illustration only, and not for limiting the invention as defined by the appended claims and their equivalents.

1. A susceptor for semiconductor manufacturing equipment, comprising:
a ceramic heater-block for installation within a processing chamber of semiconductor manufacturing equipment;
an electroconductive component formed in the interior and/or on the surface of said ceramic heater-block;
an electrode connected to said electroconductive component for supplying electricity thereto, said electrode being defined from where said electrode connects with said electroconductive component, to outside the processing chamber when said ceramic heater-block is installed therein.

2. A susceptor as set forth in claim 1, further comprising a tubular piece formed encompassing said electrode.

3. A susceptor as set forth in claim 2, further comprising a tubular piece formed encompassing said electrode; wherein an inert gas is introduced into the interior of said tubular piece.

4. A susceptor as set forth in claim 2, wherein the space within the interior of said tubular piece is isolated from the atmosphere inside the processing chamber when said ceramic heater-block is installed therein; and an inert gas is introduced into the interior of said tubular piece.

5. Semiconductor manufacturing equipment in which is installed a susceptor as set forth in claim 1.

6. Semiconductor manufacturing equipment in which is installed a susceptor as set forth in claim 2.

7. Semiconductor manufacturing equipment in which is installed a susceptor as set forth in claim 3.

8. Semiconductor manufacturing equipment in which is installed a susceptor as set forth in claim 4.
